(19) United States
(12) Patent Application Publication
(10) Pub. No.: US 2023/0411491 A1
(43) Pub. Date: Dec. 21, 2023

(54) METHODS FOR MAKING SEMICONDUCTOR DEVICES WITH SUPERLATTICE AND EMBEDDED QUANTUM DOTS

(71) Applicant: ATOMERA INCORPORATED, LOS GATOS, CA (US)

(72) Inventors: MAREK HYTHA, BROOKLINE, MA (US); NYLES WYNN CODY, TEMPE, AZ (US); ROBERT J. MEARS, WELLESLEY, MA (US); HIDEKI TAKEUCHI, SAN JOSE, CA (US); KEITH DORAN WEEKS, CHANDLER, AZ (US)

(21) Appl. No.: 18/338,415

(22) Filed: Jun. 21, 2023

Related U.S. Application Data
(60) Provisional application No. 63/366,698, filed on Jun. 21, 2022.

(51) Int. Cl. H01L 29/66; H01L 21/02

(52) U.S. Cl. CPC H01L 29/66484; H01L 21/02532; H01L 21/02601

(57) ABSTRACT

A method for making a semiconductor device may include forming at least one semiconductor layer including a superlattice therein. The superlattice may include a plurality of stacked groups of layers, with each group of layers including stacked base semiconductor monolayers defining a base semiconductor portion, and at least one non-semiconductor monolayer constrained within a crystal lattice of adjacent base semiconductor portions. The method may further include forming quantum dots spaced apart in the at least one semiconductor layer above the superlattice and including a different semiconductor material than the semiconductor layer.

### CROSS-REFERENCE TO RELATED APPLICATIONS

The present disclosure claims the benefit of U.S. Provisional App. No. 63/366,698 filed Jun. 21, 2022, which is hereby incorporated herein in its entirety by reference.

### TECHNICAL FIELD

The present disclosure generally relates to semiconductor devices, and, more particularly, to semiconductor quantum devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an re-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include forming at least one semiconductor layer including a superlattice therein. The superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. The method may further include forming a plurality of quantum dots spaced apart in the at least one semiconductor layer above the superlattice and comprising a different semiconductor material than the semiconductor layer.

In an example embodiment, forming the at least one semiconductor layer may include forming an epitaxial semiconductor layer including the superlattice therein on the substrate, and the quantum dots may be above the superlattice within the epitaxial semiconductor layer. In some embodiments, the semiconductor substrate and the epitaxial semiconductor layer may comprise silicon, and the epitaxial semiconductor layer may have a higher percentage of silicon 28 (²⁸Si) than the semiconductor substrate. By way of example, the quantum dots may comprise germanium, gallium arsenide, etc.

In an example implementation, the method may also include forming spaced apart source and drain regions in the epitaxial semiconductor layer defining a channel region therebetween, and forming a gate above the channel region on the epitaxial semiconductor layer. By way of example, the gate may comprise at least one accumulation gate, at least one plunger gate, and/or at least one barrier gate. Also by way of example, the at least one non-semiconductor may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4A is a graph of the calculated band structure from the gamma point (G) for both bulk silicon as in the prior art, and for the 4/1 Si/O superlattice as shown in FIGS. 1-2.

FIG. 4B is a graph of the calculated band structure from the Z point for both bulk silicon as in the prior art, and for the 4/1 Si/O superlattice as shown in FIGS. 1-2.

FIG. 4C is a graph of the calculated band structure from both the gamma and Z points for both bulk silicon as in the prior art, and for the 5/1/3/1 Si/O superlattice as shown in FIG. 3.

FIG. 5 is a cross-sectional diagram of a semiconductor device including embedded quantum dots in an epitaxial layer with a superlattice in accordance with an example embodiment.

FIG. 6 is a partial view of the semiconductor device of FIG. 5 showing electronvolt (eV) levels associated with different portions thereof.

FIGS. 7A-7F are a series of cross-sectional diagrams illustrating an example method for making embedded quantum dots in an epitaxial layer with a superlattice therein in an example embodiment.

FIGS. 8A-8F are a series of cross-sectional diagrams illustrating another example method for making embedded quantum dots in an epitaxial layer with a superlattice therein in an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. Applicant theorizes, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicants use a “conductivity reciprocal effective mass tensor”, Mₑ⁻¹ and Mₕ⁻¹ for electrons and holes respectively, defined as:

$${M}_{e , ij}^{- 1} ( {E}_{F} , T ) = \frac{{\sum }_{E > {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E > {E}_{F}} {\int }_{B . Z .} f ( E ( k , n ) , {E}_{F} , T ) {d}^{3} k}$$

for electrons and:

$${M}_{h , i j}^{- 1} ( {E}_{F} , T ) = \frac{- {\sum }_{E < {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E < {E}_{F}} {\int }_{B . Z .} ( 1 - f ( E ( k , n ) , {E}_{F} , T ) ) {d}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicant's definition of the conductivity reciprocal effective mass tensor is such that a tensorial component of the conductivity of the material is greater for greater values of the corresponding component of the conductivity reciprocal effective mass tensor. Again Applicant theorizes without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

Applicant has identified improved materials or structures for use in semiconductor devices. More specifically, Applicant has identified materials or structures having energy band structures for which the appropriate conductivity effective masses for electrons and/or holes are substantially less than the corresponding values for silicon. In addition to the enhanced mobility characteristics of these structures, they may also be formed or used in such a manner that they provide piezoelectric, pyroelectric, and/or ferroelectric properties that are advantageous for use in a variety of different types of devices, as will be discussed further below.

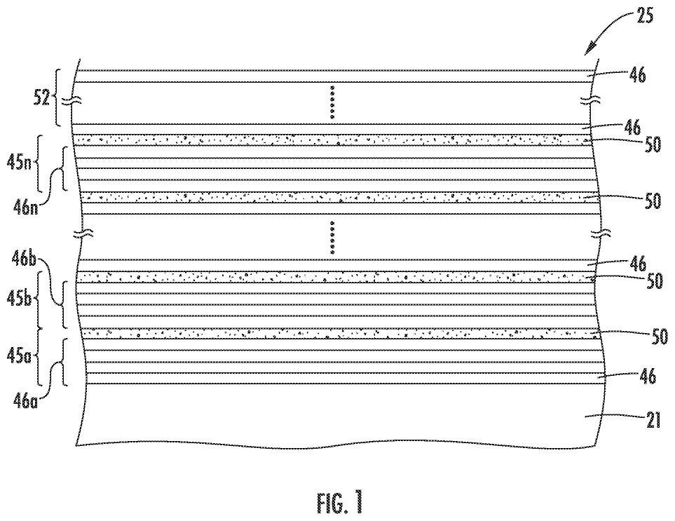

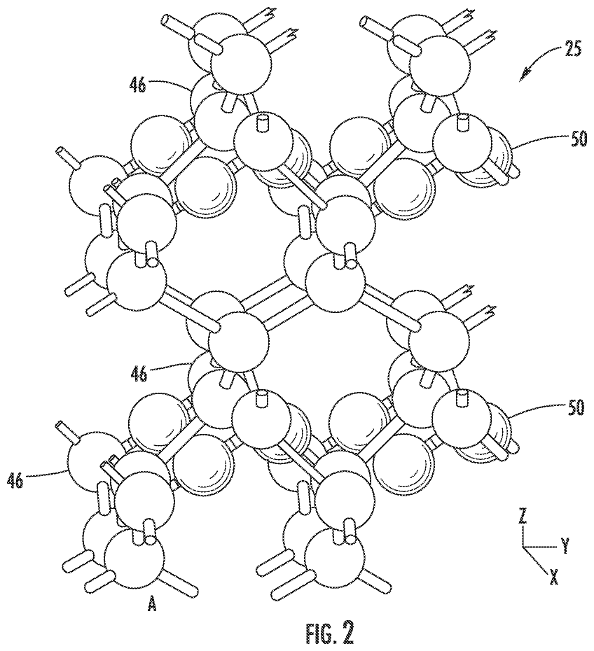

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and an energy band-modifying layer thereon. The energy band-modifying layers 50 are indicated by stippling in FIG. 1 for clarity of illustration.

The energy band-modifying layer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example

It should be noted that the term monolayer is meant to include a single atomic layer and also a single molecular layer. It is also noted that the energy band-modifying layer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicant wishing to be bound thereto that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 1 and 2, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons and holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art.

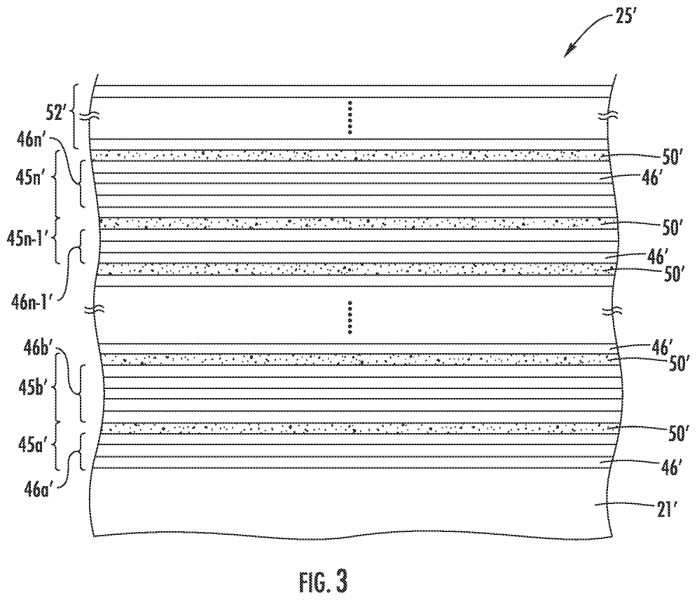

Indeed, referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

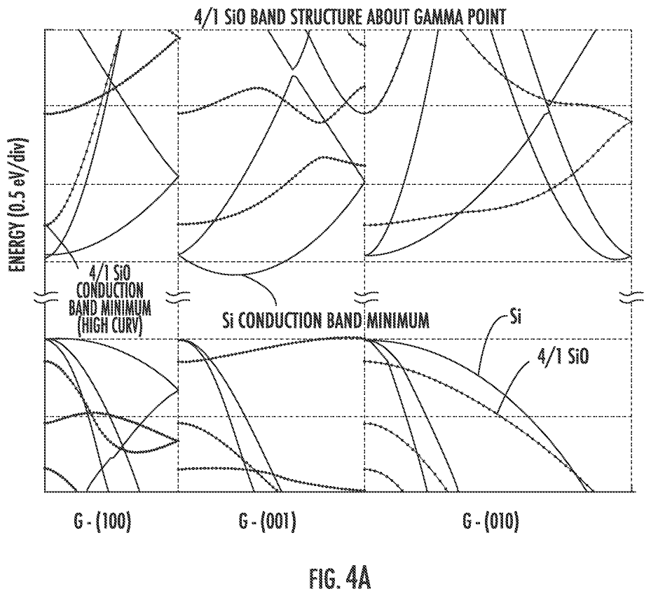

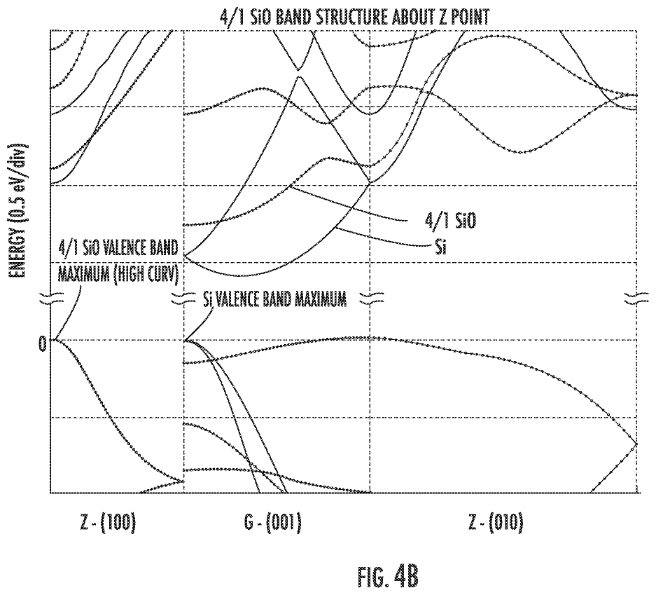

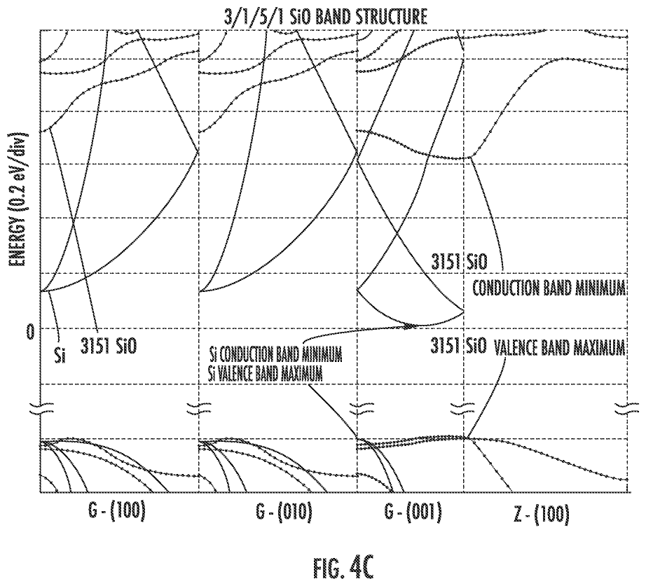

In FIGS. 4A-4C, band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 4A shows the calculated band structure from the gamma point (G) for both bulk silicon (represented by continuous lines) and for the 4/1 Si/O superlattice 25 shown in FIG. 1 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 4B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 4C shows the calculated band structure from both the gamma and Z point for both bulk silicon (continuous lines) and for the 5/1/3/1 Si/O structure of the superlattice 25′ of FIG. 3 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicant to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

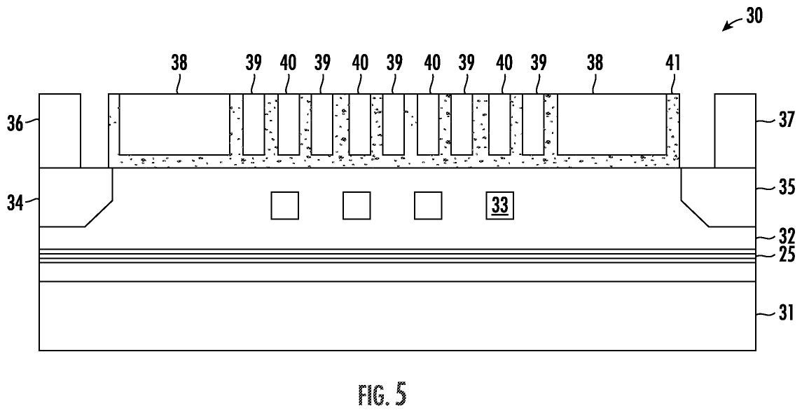

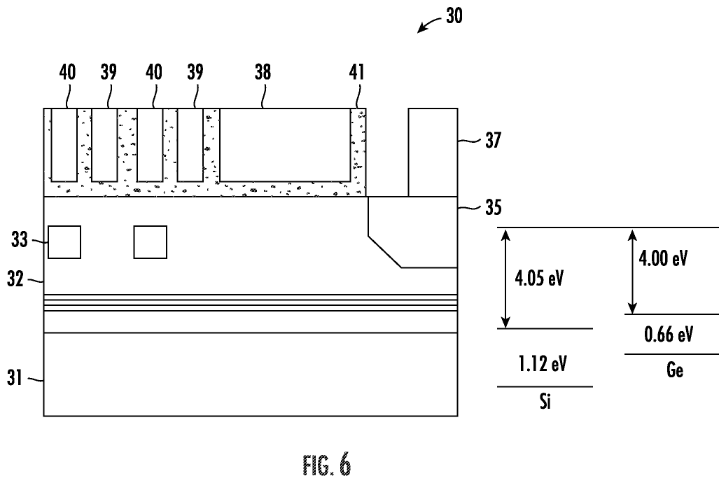

Referring now additionally to FIGS. 5-6, the above-described superlattice structures may advantageously be used in the fabrication of semiconductor wafers and devices which include embedded quantum dots. By way of background, several characteristics have been identified which are important for quantum device applications. One is scalability, that is the capability to be a scalable physical system with well-defined qubits. Another characteristic is initialization, in that the system should be initializable to a simple fiducial state such as |000 . . . >. Still another characteristic is decoherence, in that the system should have gate operation times that are much smaller than the decoherence time (e.g., 10⁴-10⁵×“clock time”, then error-correction is feasible). A fourth characteristic is universality, in that the system should have a universal set of quantum gates (CNOT). The last characteristic is measurement, in that the system should have qubit-specific high-fidelity measurement capability. These characteristics may be realized with a silicon spin-based qubit. However, in many cases this may require a relatively pure ²⁸Si substrate.

More particularly, ²⁸Si provides certain advantages, as well as challenges, with respect to semiconductor quantum devices. The advantages include higher thermo-conductivity for better heat dissipation, and higher decoherence time, which enables qubits. However, ²⁸Si may also suffer from silicon inter-diffusion, and is relatively expensive to grow.

The metal oxide semiconductor (MOS) device 30 illustrated in FIG. 5 is a spin qubit device which illustratively includes a silicon substrate 31, which may be a natural or typical silicon material (e.g., non-²⁸Si enriched). An epitaxial layer 32 of enriched ²⁸Si is grown on the substrate 31, although non-²⁸Si enriched epitaxy or other semiconductor materials (e.g., Ge) may be used in other embodiments. In the illustrated example, the epitaxial layer 33 further includes a superlattice 25 therein. That is, an MST film formation module may be performed during the epitaxial layer growth, such that the superlattice 25 is grown on a relatively thin seed layer of epitaxial enriched ²⁸Si, and the cap layer of the superlattice defines the upper portion of the epitaxial layer 32. As discussed above, the crystal lattice of the enriched ²⁸Si material traverses the superlattice layer 25, and thus the epitaxial layer 32 is treated as a single layer with an embedded MST film herein, although it could also be considered two separate epitaxial enriched ²⁸Si layers with an MST film therebetween. In some embodiments, another MST film(s) may be incorporated within the epitaxial layer 32, or grown on top of it, if desired.

The semiconductor device 30 further illustratively includes a plurality of quantum dots 33 spaced apart in the epitaxial layer 32 above the superlattice 25. The quantum dots 33 include a different semiconductor material than the epitaxial layer 32. More particularly, the quantum dots 33 may include a semiconductor such as germanium (Ge) or gallium arsenide (GaAs), for example, although other suitable materials may be used in different embodiments.

The substrate 31 and epitaxial layer 32 with superlattice 25 and quantum dots 33 may collectively be considered an ²⁸Si quantum substrate which provides numerous advantages for quantum applications. First, this allows a relatively small or thin amount of ²⁸Si to be used, as compared to conventional ²⁸Si approaches where a relatively thick layer is required to prevent undesired isotope intermixing. This is significant due to the higher cost of ²⁸Si deposition, as the ²⁸Si quantum substrate requires less ²⁸Si gas during formation. Moreover, incorporation of the MST film in the ²⁸Si quantum substrate advantageously helps eliminate point defects, provides better thermostability, and helps preserve a higher ²⁸Si purity. In particular, the dopant blocking properties of the superlattice 25 discussed above help block contaminants (e.g., boron) from migrating towards the quantum dots 33. Example devices in which the ²⁸Si quantum substrate may be utilized include silicon spin qubits (as in the present example shown in FIG. 5), as well as quantum sensors, Single Electron Transistors (SETs), Resonant Tunneling Diodes (RTDs), and trench FET (TFET) devices.

The semiconductor device 30 further illustratively includes spaced apart source and drain regions 34, 35 in the epitaxial semiconductor layer 32 defining a channel region therebetween where the quantum dots 33 are located. Respective source/drain contacts 36, 37 are formed on the source and drain regions 34, 35. Furthermore, a gate structure is above the channel region on the epitaxial layer 32 which illustratively includes accumulation gate electrodes 38, barrier gate electrodes 39, and plunger gate electrodes 40, as well as a gate dielectric layer 41, as shown. In the example illustrated in FIG. 6, the quantum dots are Ge, and corresponding eV values for Si and Ge are shown to the right of the example implementation.

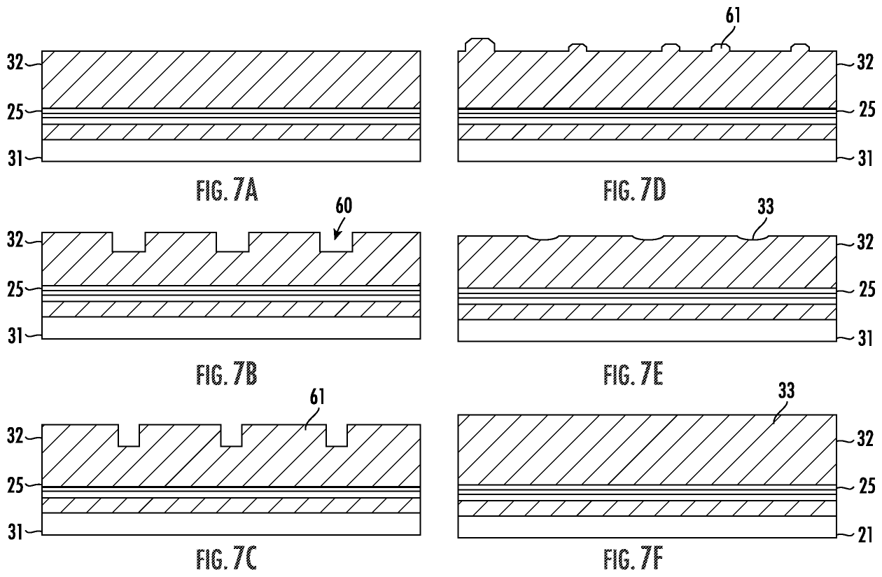

A first example approach for fabricating a ²⁸Si quantum substrate as set forth above is now described with reference to FIGS. 7A-7F. After forming the epitaxial layer 32 on the substrate 31 (FIG. 7A), a pattern of small (e.g., less than 10 nanometer) holes or pits 60 are formed in the epitaxial (crystalline) layer 32 (FIG. 7B). The holes 60 may then be filled with the quantum dot material (e.g., Ge) 61, as seen in FIGS. 7C and 7D, and the surface of the epitaxial layer 32 is cleaned (e.g., using CMP) to remove excess Ge and define the quantum dots 33 (FIG. 7E). Additional silicon (e.g., enriched ²⁸Si) is epitaxially grown to embed the quantum dots 33 in the epitaxial layer 32 (FIG. 7F). At this stage the ²⁸Si quantum substrate may be used for fabricating various quantum devices, such as those described further above.

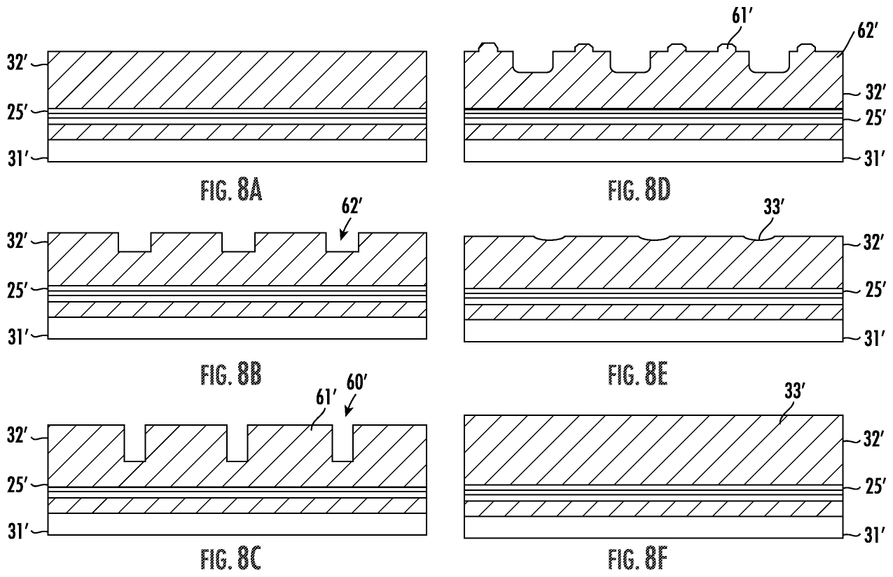

In an alternative embodiment now described with reference to FIGS. 8A-8F, after formation of the epitaxial layer 32′ with superlattice 25′ (FIG. 8A), an oxide mask 62′ is formed on the epitaxial layer which is used to define the holes 60′ in the desired locations (FIG. 8C), and the quantum dot material 61′ is deposited through the oxide mask (FIG. 8D). The oxide mask 62′ is then removed (FIG. 8E), and additional silicon is epitaxially grown on the structure to produce the embedded quantum dots 33′ (FIG. 8F).

By way of example, the epitaxial layers 32, 32′ may have a concentration of ²⁸Si isotope greater than 93%, and more particularly greater than 99%, for example. Further details regarding ²⁸Si and MST films are provided in U.S. App. Nos. US 2022/0344155 and 2022/0352322, both to Hytha et al., and both of which are hereby incorporated herein in their entireties by reference.

Generally speaking, the above-described approach advantageously provides a method for growing very small, uniformly distributed quantum dots 33, 33′ which, due to its size and Coulomb blockade, would be essentially single electron (hole) quantum dots. In some implementations this may be combined with control by gate, as discussed further above. Furthermore, it should be noted that ²⁸Si is but one option for the epitaxial layer 32, 32′, which while helpful for qubit applications, is not required for other applications such as single electron transistors (SETs), for example. Furthermore, it should be noted that in some embodiments, an MST film need not be present in the epitaxial layer 32, 32′.

As also noted above, other materials besides silicon with germanium/GaAs quantum dots may be used in different embodiments. As an example alternative substrate/epitaxial layer material, a wide band gap semiconductor such SiC or GaN may be used. Other example materials which may be used for quantum dots include Si, SiC, GaN, InP, etc.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included.

1. A method for making a semiconductor device comprising:
forming at least one semiconductor layer including a superlattice therein, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
forming a plurality of quantum dots spaced apart in the at least one semiconductor layer above the superlattice and comprising a different semiconductor material than the semiconductor layer.

2. The method of claim 1 wherein forming the at least one semiconductor layer comprises forming a semiconductor substrate and an epitaxial semiconductor layer on the substrate with the superlattice within the epitaxial semiconductor layer; and wherein the quantum dots are above the superlattice within the epitaxial semiconductor layer.

3. The method of claim 2 wherein the semiconductor substrate and the epitaxial semiconductor layer comprise silicon; and wherein the epitaxial semiconductor layer has a higher percentage of silicon 28 (²⁸Si) than the semiconductor substrate.

4. The method of claim 1 wherein the plurality of quantum dots comprise germanium.

5. The method of claim 1 wherein the plurality of quantum dots comprise gallium arsenide.

6. The method of claim 2 further comprising forming spaced apart source and drain regions in the epitaxial semiconductor layer defining a channel region therebetween, and forming a gate above the channel region on the epitaxial semiconductor layer.

7. The method of claim 6 wherein the gate comprises at least one accumulation gate.

8. The method of claim 6 wherein the gate comprises at least one plunger gate.

9. The method of claim 6 wherein the gate comprises at least one barrier gate.

10. The method of claim 1 wherein the at least one non-semiconductor comprises oxygen.

11. A method for making a semiconductor device comprising:
forming an epitaxial semiconductor layer including a superlattice therein above a semiconductor substrate, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
forming a plurality of quantum dots spaced apart in the epitaxial semiconductor layer above the superlattice and comprising a different semiconductor material than the epitaxial semiconductor layer;
forming spaced apart source and drain regions in the epitaxial semiconductor layer defining a channel region therebetween; and
forming a gate above the channel region on the epitaxial semiconductor layer.

12. The method of claim 11 wherein the semiconductor substrate and the epitaxial semiconductor layer comprise silicon; and wherein the epitaxial semiconductor layer has a higher percentage of silicon 28 (²⁸Si) than the semiconductor substrate.

13. The method of claim 11 wherein the gate comprises at least one of an accumulation gate, a plunger gate, and a barrier gate.

14. The method of claim 11 wherein the plurality of quantum dots comprise germanium.

15. The method of claim 11 wherein the plurality of quantum dots comprise gallium arsenide.

16. A method for making a semiconductor device comprising:
forming at least one silicon layer including a superlattice therein, the superlattice comprising a plurality of stacked groups of layers, each group of layers comprising a plurality of stacked base silicon monolayers defining a base silicon portion, and at least one oxygen monolayer constrained within a crystal lattice of adjacent base semiconductor portions; and
forming a plurality of quantum dots spaced apart in the at least one silicon layer above the superlattice and comprising germanium.

17. The method of claim 16 wherein forming the at least one silicon layer comprises forming an epitaxial silicon layer with the superlattice therein on a silicon substrate; and
wherein the quantum dots are above the superlattice within the epitaxial silicon layer.

18. The method of claim 17 wherein the silicon substrate and the epitaxial silicon layer comprise silicon; and wherein the epitaxial silicon layer has a higher percentage of silicon 28 (²⁸Si) than the silicon substrate.

19. The method of claim 16 further comprising forming spaced apart source and drain regions in the epitaxial semiconductor layer defining a channel region therebetween, and forming a gate above the channel region on the epitaxial semiconductor layer.

20. The method of claim 16 wherein the gate comprises at least one of an accumulation gate, a plunger gate, and barrier gate.
